(19) United States
(12) Patent Application Publication
(10) Pub. No.: US 2010/0164058 A1
(43) Pub. Date: Jul. 1, 2010

(54) CHIP PACKAGE WITH STACKED INDUCTORS

(76) Inventors: Jeff BIAR, Taipei County (TW); Jacky Lee, Taipei County (TW)

Correspondence Address: Muncy, Geissler, Olds & Lowe, PLLC, 4000 Legato Road, Suite 310, FAIRFAX, VA, 22033, US

(21) Appl. No.: 12/429,870

(22) Filed: Apr. 24, 2009

(30) Foreign Application Priority Data
Dec. 25, 2008 (TW) 97223316

(51) Int. Cl. H01L 27/04

(52) U.S. Cl. 257/531; 257/E27.01

(57) ABSTRACT

A semiconductor chip package with inductors includes a substrate, a semiconductor chip, an inductor and an insulator cover. The substrate has an active surface with a patterned circuit thereon. The inductor disposes on the active surface of the substrate. The semiconductor chip stacks over the inductor and electrically interconnects with the patterned circuit of the substrate and the inductor. The insulator cover encapsulates the inductor and the chip.

### BACKGROUND OF THE INVENTION

1. Field of the Invention

The present invention relates to semiconductor chip packages, and more particularly, to semiconductor chip packages with stacked inductors.

2. Description of the Related Art

To satisfy the demand for a small size semiconductor chip with inductors, U.S. Pat. No. 6,512,285 discloses a structure for integrating an inductor on a package substrate of a chip. From the disclosure thereof, such a structure indeed reduces the size of the prior art chip. But as shown in FIG. 1 thereof, in the structure, an inductor 108 and a chip 102 are situated on top surface 104 of substrate 106. In other words, inductor 108 and chip 102 are arranged on the same plane. The result is that the structure needs a large size substrate to accommodate both inductor and chip so that the size of the whole chip package can not be substantially reduced.

The primary objective of the invention therefore is to reduce the size of a chip package with inductors.

Another objective of the invention is to provide a chip package having a small size inductor stacked thereon.

### SUMMARY OF THE INVENTION

Thus, a chip package according to the invention comprises a substrate, a semiconductor chip, an inductor and an insulator cover. The substrate has an active surface with a patterned circuit thereon. The inductor attaches on the active surface of the substrate. The semiconductor chip stacks over the inductor and electrically interconnects with the patterned circuit of the substrate and the inductor. The insulator cover encapsulates the inductor and the chip.

### BRIEF DESCRIPTION OF THE DRAWINGS

The above and other objectives, advantages and features of the invention will become clearer from the following description of the preferred embodiment with reference to the attached drawings, wherein:

FIG. 1 is a sectional view of a first embodiment of the invention;

FIG. 2 is a sectional view of a second embodiment of the invention;

FIG. 3 is a partly exploded view of the chip package as shown in FIG. 2;

FIG. 4 is a sectional view of a third embodiment of the invention; and

FIG. 5 is a perspective view of an inductor of the chip package as shown in FIG. 4.

### DETAILED DESCRIPTION OF PREFERRED EMBODIMENTS

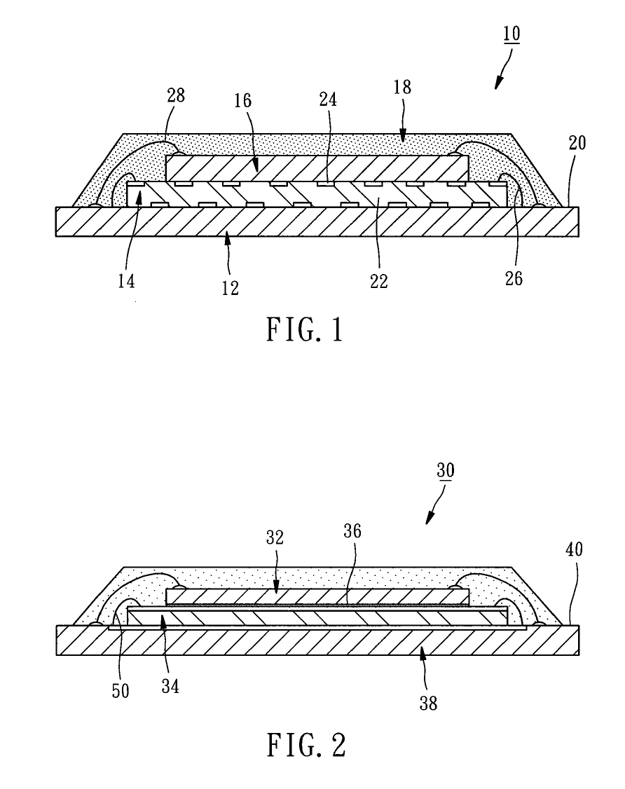

Referring firstly to FIG. 1, a chip package 10 according to one embodiment of the invention includes a substrate 12, an inductor 14, a semiconductor chip 1 6 and an insulator cover 18.

Substrate 12 is a conventional substrate for chip packaging, such as PCB. It has an active surface 20 with a patterned circuit.

Inductor 14 includes a core 22 made of a material with high permeability, such as ferrite, and a coil 24 encircling thereon. In this embodiment, a first insulator layer (not shown in the drawing) disposes between inductor 14 and active surface 20 of substrate 12. Inductor 14 is electrically interconnected to the patterned circuit of active surface 20 of substrate 12 by conductive wires 26.

Semiconductor chip 16 is stacked over inductor 14. A second insulator layer (not shown in the drawing) disposes between chip 16 and inductor 14. Chip 16 is electrically interconnected to the patterned circuit of active surface 20 of substrate 12 by conductive wires 28.

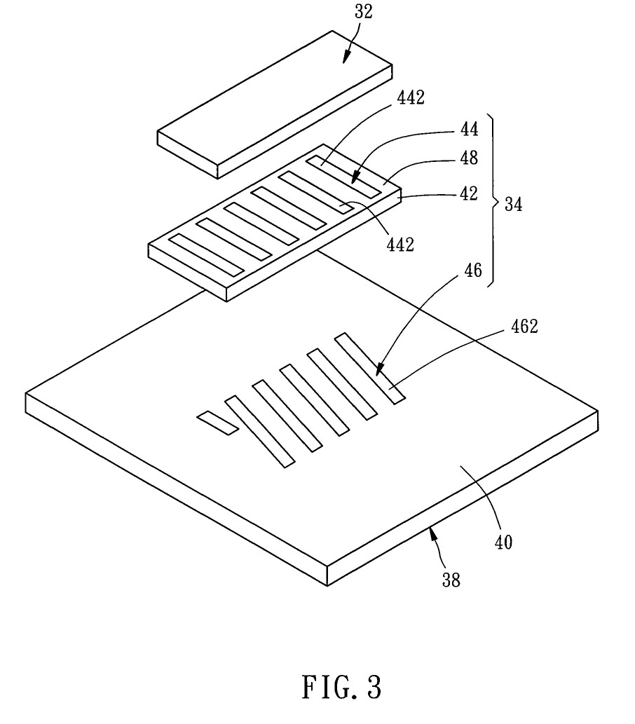

Referring now to FIGS. 2 and 3, chip package 30 according to another embodiment of the invention includes a semiconductor chip 32 and inductor 34, which are orderly stacked over active surface 40 of substrate 38. In this embodiment, inductor 34, as shown in FIG. 3, includes a core 42 made of ferrite, an upper winding 44 and a lower winding 46. Upper winding 44 has a plurality of first conductive segments 442 disposed on upper surface 48 of core 42 by any prior art method, such as embedded or coated processing. Lower winding 46 also has a plurality of second conductive segments 462 disposed on active surface 40 of substrate 38 by any prior art method, such as coating or printing processing. Upper winding 44 and lower winding 46 are electrically interconnected by bonding wires 50 so as to form a complete coil of inductor 34.

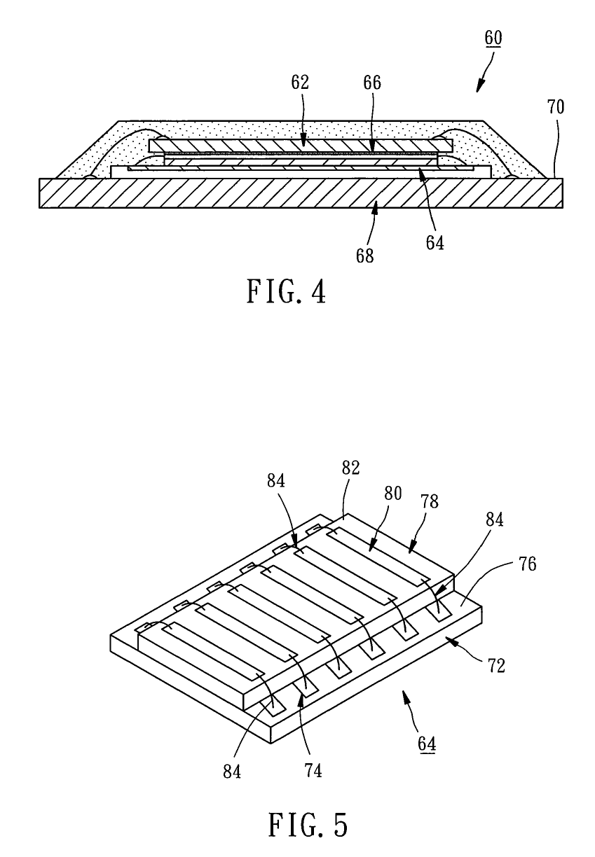

Referring lastly to FIGS. 4 and 5, chip package 60 is similar to chip packages 10 and 30 wherein chip 62 and inductor 64 are orderly stacked on active surface 70 of substrate 68 and an insulator layer 66 is disposed between chip 62 and inductor 64. The difference among them is that, in this embodiment, inductor 64 includes a base 72 made of insulating materials, a lower winding 74 is disposed on upper surface 76 of base 72, a core 78 made of ferrite is stacked over lower winding 74, an upper winding 80 is disposed on upper surface 82 of core 78, and upper winding 80 and lower winding 74 are electrically interconnected by bonding wires 84.

It is manifest from the above description of the invention that the chip and the inductor are orderly stacked over the substrate so that the size of the whole chip package is substantially reduced.

It should be understood that the invention is not limited to the particular embodiments described herein, but is capable of many rearrangements, modifications, and substitutions without departing from the scope of the invention.

What is claimed is:

1. A chip package, comprising:
a substrate having an active surface with a patterned circuit thereon;
an inductor attached on said active surface of said substrate;
a semiconductor chip stacked over said inductor and electrically interconnected with said patterned circuit and said inductor; and
an insulator cover encapsulating said inductor and said chip.

2. The chip package of claim 1, wherein said inductor includes a core made of a material with high permeability, and a coil encircling on said core.

3. The chip package of claim 1, further comprising a first insulator layer disposed between said inductor and said substrate.

4. The chip package of claim 1, further comprising a second insulator layer disposed between said inductor and said chip.

5. The chip package of claim 1, wherein said inductor includes:
a base having an upper surface;
a plurality of first conductive segments separately disposed on said upper surface of said base;
a core made of a material with high permeability stacked over said first conductive segments; and
a plurality of second conductive segments separately disposed on said core, said second conductive segments electrically interconnecting with said first conductive segments to form an inductor coil.

6. A chip package, comprising:
a substrate having an active surface with a patterned circuit thereon;
a semiconductor chip attached on said active surface of said substrate and electrically interconnected with said patterned circuit thereof;
an inductor disposed between said substrate and said chip, said inductor includes:
a lower winding disposed on said active surface of said substrate;
a core made of a material with high permeability stacked over said lower winding;
an upper winding disposed on said core; and
said lower winding electrically interconnected with said upper winding to form an inductor coil; and
an insulator cover encapsulating said inductor and said chip.

7. The chip package of claim 6, wherein said lower winding includes a plurality of first conductive segments separately disposed on said active surface of said substrate.

8. The chip package of claim 6, wherein said upper winding includes a plurality of second conductive segments separately disposed on said core.

9. The chip package of claim 8, wherein said first conductive segments and said second conductive segments are electrically interconnected by a plurality of bonding wires.
